(19) United States
(12) Patent Application Publication
(10) Pub. No.: US 2024/0377145 A1
(43) Pub. Date: Nov. 14, 2024

(54) SUBSTRATE PROCESSING DEVICE

(71) Applicant: ASM IP Holding B.V., Almere (NL)

(72) Inventors: SungBae Kim, Yongin-si (KR); KwangMan Ko, Uiwang-si (KR); Juill Lee, Cheonan-si (KR)

(21) Appl. No.: 18/654,213

(22) Filed: May 3, 2024

Related U.S. Application Data
(60) Provisional application No. 63/464,662, filed on May 8, 2023.

(51) Int. Cl. F28F 3/12; H01L 21/67

(52) U.S. Cl. CPC F28F 3/12; H01L 21/67098

(57) ABSTRACT

Disclosed is a heat shielding device which shields heat from a chamber wall to the outside by creating one or more gas insulating layers around a chamber heated to a high temperature, thereby reducing heat loss, power consumed when heating the chamber to a certain temperature, minimizing the effect of heat to another chamber and reducing safety problems such as burning of an operator.

### CROSS-REFERENCE TO RELATED APPLICATIONS

This application claims priority to U.S. Provisional Patent Application Ser. No. 63/464,662 filed May 8, 2023 titled SUBSTRATE PROCESSING DEVICE, the disclosure of which is hereby incorporated by reference in its entirety.

### BACKGROUND

### 1. Field

One or more example embodiments relate to a substrate processing device, and more particularly, to a substrate processing device capable of shielding heat due to chamber heating.

### 2. Description of Related Art

A semiconductor device is manufactured by processing a silicon substrate through various processing devices. A process of manufacturing the semiconductor device includes a front-end process and a back-end process. The front-end process is a process of processing a silicon substrate while repeating processes such as photolithography, deposition, and etching. In particular, the deposition process of the front-end process is a process for forming a thin film by supplying reactive gases onto a substrate to cause a chemical reaction. The chemical reaction includes a process for activating a surface of the substrate or reactive gas to cause a reaction between the substrate and the reactive gas. In general, this activation process includes a thermal process using heat or a plasma process using plasma.

For the thermal process, a component mounting a substrate and a device surrounding the component are heated to a certain temperature. For example, a substrate mounting portion, such as a heating block and a susceptor, is heated to a temperature of 300 degrees or more, a chamber wall surrounding the substrate mounting portion is heated to a temperature of 150 degrees or more, and a reaction space is maintained at a certain temperature such that a thermal process is possible.

However, maintaining the substrate processing device at a high temperature causes safety problems such as burning of an operator.

FIGS. 1 and 2 schematically illustrate a substrate processing device of the prior art for solving such safety problems.

Referring to FIGS. 1 and 2, a conventional substrate processing device includes a chamber 1, a first insulating plate 2 attached to an outer wall of the chamber 1, and a second insulating plate 3 apart from the first insulating plate 2. The second insulating plate 3 is disposed apart from the first insulating plate 2 by a support 4. A gas insulating layer a is defined by the first insulating plate 2, the support 4, and the second insulating plate 3 and is formed between the outer wall of the chamber 1 and an outer space. The gas insulating layer a blocks heat of the chamber 1 from transmitting to the outer space.

As such, the substrate processing device of the prior art blocks heat from the chamber 1 by using the two insulating plates, that is, the first and second insulating plates 2 and 3. However, since the first insulating plate 2 is in close contact with a wall of the chamber 1, heat of the wall of the chamber 1 is directly transmitted to the first insulating plate 2, which limits effective shielding of the heat by the two insulating plates, that is, the first and second insulating plates 2 and 3, and the gas insulating layer a.

### SUMMARY

One or more embodiments include a device for solving the above-mentioned problems. In particular, one or more embodiments include a device for effectively shielding heat generated by chamber heating.

Additional aspects will be set forth in part in the description which follows and, in part, will be apparent from the description, or may be learned by practice of the presented embodiments of the disclosure.

According to one or more embodiments, a substrate processing device includes: a chamber; a first insulating plate apart from an outer wall of the chamber by a first preset distance; and a second insulating plate apart from the first insulating plate by a second preset distance, wherein the first insulating plate may be located between the outer wall of the chamber and the second insulating plate.

According to a further example of the substrate processing device, the first preset distance may be equal to or greater than the second preset distance.

According to a further example of the substrate processing device, a first space is between the outer wall of the chamber and the first insulating plate, a second space is between the first insulating plate and the second insulating plate, and the substrate processing device may further include a refrigerant supplier for supplying refrigerant to the second space.

According to a further example of the substrate processing device, the substrate processing device may further include an additional refrigerant supplier for supplying refrigerant to the first space.

According to a further example of the substrate processing device, the substrate processing device may further include a suction unit for sucking gas in the first space and the second space.

According to a further example of the substrate processing device, the refrigerant supplier and the additional refrigerant supplier may control at least one of the temperature and the flow rate of refrigerant such that temperature of the second space is lower than temperature of the first space.

According to another example of the substrate processing device, at least one gap is in the first insulating plate, and the first space and the second space may communicate with each other through the gap.

According to a further example of the substrate processing device, the at least one gap may be located below the first insulating plate.

According to a further example of the substrate processing device, the substrate processing device may further include a suction unit for sucking gas in the first space.

According to a further example of the substrate processing device, the substrate processing device may further include: a gas supplier for supplying gas into the chamber; and an exhauster connected to the gas supplier and the suction unit.

According to a further example of the substrate processing device, the relationship of pressure of the second space>pressure of the first space>pressure of the suction unit>the pressure of the exhauster is satisfied, and the relationship of pressure of the gas supplier>pressure of the suction unit>pressure of the exhauster is satisfied.

According to one or more embodiments, a substrate processing device includes: a chamber; a first insulating plate surrounding the chamber and apart from the chamber; and a second insulating plate surrounding the first insulating plate and apart from the first insulating plate chamber.

According to a further example of the substrate processing device, a first space may be between the outer wall of the chamber and the first insulating plate, a second space may be between the first insulating plate and the second insulating plate, and the substrate processing device may further include at least one refrigerant supplier communicating with the first space or the second space.

According to a further example of the substrate processing device, the at least one refrigerant supplier may communicate with the second space, at least one gap may be in the first insulating plate, and the first space and the second space may communicate with each other through the gap.

According to a further example of the substrate processing device, the at least one gap may be located opposite the at least one refrigerant supplier with respect to the chamber.

According to a further example of the substrate processing device, the substrate processing device may further include a suction unit for sucking gas in the first space, and the suction unit may be located opposite the at least one gap with respect to the chamber.

According to a further example of the substrate processing device, temperature of refrigerant flowing into the first space may be higher than temperature of refrigerant flowing into the second space.

According to another example of the substrate processing device, at least one gap may be in the first insulating plate, and the first space and the second space may communicate with each other through the gap, and the substrate processing device may include: two or more gas suppliers symmetrically arranged in at least one of the first space and the second space; and two or more suction units symmetrically arranged in at least one of the first space and the second space.

According to one or more embodiments, a substrate processing device includes: a chamber; a plurality of first insulating plates respectively forming a plurality of first spaces together with one outer wall of the chamber; and a plurality of second insulating plates respectively forming a plurality of second spaces together with one of the plurality of first insulating plates, wherein each of the plurality of first insulating plates is between one outer wall of the chamber and one of the plurality of second insulating plates, the plurality of first spaces may be apart from each other, and the plurality of second spaces may be apart from each other.

According to a further example of the substrate processing device, each of the plurality of second spaces may communicate with at least one refrigerant supplier.

According to one or more embodiments, a substrate processing device may include: a chamber; a first insulating plate disposed on an outer wall of the chamber; a second insulating plate spaced apart from the first insulating plate; a metal plate disposed between the first insulating plate and the second insulating plate; and a substrate transfer channel formed to pass through the first insulating plate, the second insulating plate, and the metal plate, wherein the metal plate has a thermal conductivity of less than 30 W/mK.

According to a further example of the substrate processing device, the first insulating plate may include glass fiber and a thermosetting resin, and the thermal conductivity of the first insulating plate is less than 0.3 W/mK.

According to a further example of the substrate processing device, the metal plate may comprise stainless steel containing at least 12 wt % of chromium.

According to a further example of the substrate processing device, the metal plate may comprise 18Cr-8Ni based stainless steel.

According to a further example of the substrate processing device, a heat reflection layer may be formed on a surface of the metal plate facing the first insulating plate.

According to a further example of the substrate processing device, the heat reflection layer may include a chromium layer, and the chromium layer may be in direct contact with the metal plate.

According to a further example of the substrate processing device, the second insulating plate may comprise polycarbonate.

According to a further example of the substrate processing device, the substrate processing device may further comprise a gate valve connected to the substrate transfer channel.

According to a further example of the substrate processing device, at least a part of the gate valves may comprise an additional metal plate having a thermal conductivity of less than 30 W/mK.

According to a further example of the substrate processing device, the substrate transfer channel may extend along a first direction, and at least a portion of a thermal energy emitted from the chamber may be reflected by the metal plate to be transmitted along a second direction different from the first direction.

According to a further example of the substrate processing device, one surface of the metal plate is polished such that a heat reflecting function is performed against the thermal energy.

According to a further example of the substrate processing device, the metal plate may extend along the second direction and is configured not to include a bending portion.

According to one or more embodiments, a substrate processing device may comprise a chamber; a first insulating plate disposed on an outer wall of the chamber; and a metal plate forming a heat diffusion channel together with the first insulating plate, wherein a substrate transfer channel for transferation of the substrate in a first direction is formed between the first insulating plate and the metal plate, wherein the metal plate extends along a second direction different from the first direction, and wherein the heat diffusion channel is formed along the second direction, and the metal plate is configured to have no bending portion around the substrate transfer channel in the heat diffusion channel.

According to a further example of the substrate processing device, thermal energy emitted from the chamber may be reflected by the metal plate to be transmitted along the heat diffusion channel extending in the second direction.

According to a further example of the substrate processing device, the metal plate has a thermal conductivity of less than 30 W/mK.

According to a further example of the substrate processing device, the substrate processing device may further comprise a gate valve connected to the chamber, and the gate valve may include a body unit and a driving unit for moving the body unit.

According to a further example of the substrate processing device, at least a portion of the body portion may include an additional metal plate having a thermal conductivity of less than 30 W/mK.

According to one or more embodiments, a substrate processing device may comprise a chamber; a first insulating plate disposed on an outer wall of the chamber, the first insulating plate including glass fiber and a thermosetting resin; and a metal plate spaced apart from the first insulating plate by a predetermined distance, the metal plate including 18Cr-8Ni based stainless steel, wherein a chromium layer may be formed in direct contact with a surface of the 18Cr-8Ni based stainless steel of the metal plate facing the first insulating plate, and wherein a space exists between the first insulating plate and the metal plate.

According to a further example of the substrate processing device, the substrate processing device may further comprise a second insulating plate disposed outside the metal plate.

According to a further example of the substrate processing device, the substrate processing device may further comprise a refrigerant supplier supplying refrigerant to the space.

According to a further example of the substrate processing device, an additional space may be formed between the outer wall and the first insulating plate, the substrate processing device further includes an additional refrigerant supplier supplying refrigerant to the additional space, and the refrigerant supplier and the additional refrigerant supplier may control at least one of a temperature and a flow rate of the refrigerant so that a temperature of the space is lower than a temperature of the additional space.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view of a heat shielding device of a substrate processing device of the prior art;

FIG. 2 is a cross-sectional view of a heat shielding device of a substrate processing device of the prior art;

FIG. 3 is a cross-sectional view of a heat shielding device according to embodiments;

FIG. 4A is a cross-sectional view of a heat shielding device according to further embodiments;

FIG. 4B is a view of a refrigerant supplier according to further embodiments;

FIGS. 5 to 8 are cross-sectional views of a heat shielding device according to further embodiments;

FIG. 9 is a cross-sectional view of a substrate processing device according to embodiments;

FIGS. 10A to 10F are top views of a heat shielding device according to embodiments;

FIGS. 11A to 11C are top views of a heat shielding device according to other embodiments; and

FIG. 12 is a view of a substrate processing system according to embodiments.

FIG. 13 schematically shows a substrate processing device according to embodiments of the inventive concept.

FIG. 14 schematically shows a substrate processing device according to embodiments of the inventive concept.

FIG. 15 schematically shows a substrate processing device according to embodiments of the inventive concept.

FIG. 16 schematically shows a substrate processing device according to embodiments of the inventive concept.

FIG. 17 schematically shows a substrate processing device according to embodiments of the inventive concept.

FIG. 18 schematically shows a substrate processing device according to embodiments of the inventive concept.

FIG. 19 schematically shows a substrate processing device according to embodiments of the inventive concept.

FIG. 20 shows a comparison between the surface temperature of the transfer chamber of a substrate processing device according to embodiments of the inventive concept and the surface temperature of the transfer chamber in a conventional substrate processing device.

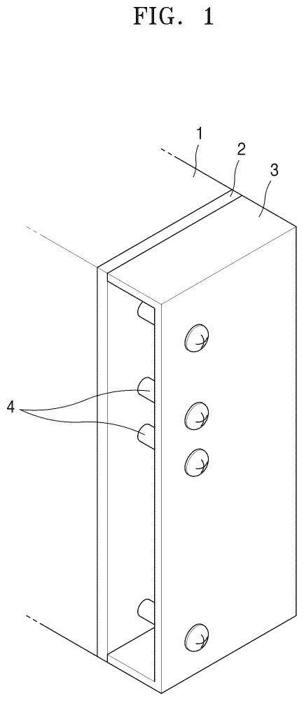

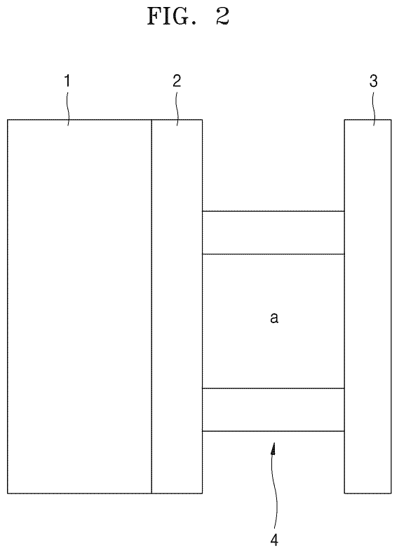

### DETAILED DESCRIPTION

Hereinafter, one or more example embodiments will be described more fully with reference to the accompanying drawings.

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, operations, members, components, and/or groups thereof, but do not preclude the presence or addition of one or more other features, integers, steps, operations, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected as a result of, for example, manufacturing techniques and/or tolerances. Thus, the embodiments of the present disclosure should not be construed as being limited to the particular shapes of regions illustrated herein but may include deviations in shapes that result, for example, from manufacturing processes.

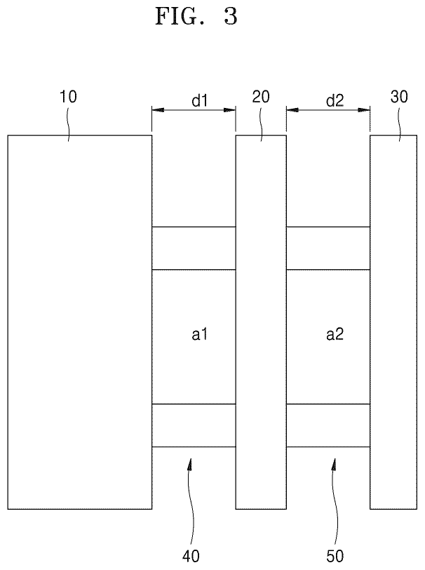

FIG. 3 is a cross-sectional view of a heat shielding device according to embodiments;

Referring to FIG. 3, a substrate processing device includes a chamber 10, a first insulating plate 20 apart from an outer wall of the chamber 10, and a second insulating plate 30 apart from the first insulating plate 20. The first insulating plate 20 is between the outer wall of the chamber 10 and the second insulating plate 30.

The first insulating plate 20 may be apart from the outer wall of the chamber 10 by a first preset distance d1 by at least one first support 40. The second insulating plate 30 may be apart from the first insulating plate 20 by a second preset distance d2 by at least one second support 50.

There may be a first space a1 between the outer wall of the chamber 10 and the first insulating plate 20 because the first insulating plate 20 is apart from the outer wall of the chamber 10, and there may be a second space a2 between the first insulating plate 20 and the second insulating plate 30 because the second insulating plate 30 is apart from the first insulating plate 20. The first space a1 and the second space a2 serve as an insulating barrier for shielding heat of the chamber 1 against an outer space.

It is possible to shield the heat of the chamber 10 more effectively by the two insulating plates, that is, the first and second insulating plates 20 and 30, and the two gas insulating layers (i.e., the first space a1 and the second space a2) between the wall of the chamber 10 and the external space.

Unlike the prior art in which the first insulating plate 2 is attached to the wall of the chamber, the present invention may prevent the heat of the chamber 10 from being directly transmitted to the first insulating plate 20 by keeping the first insulating plate 20 at a certain distance from the wall of the chamber 10. In addition, the two gas insulating layers may be formed to minimize thermal conductivity from the chamber 10 and to achieve effective heat shielding.

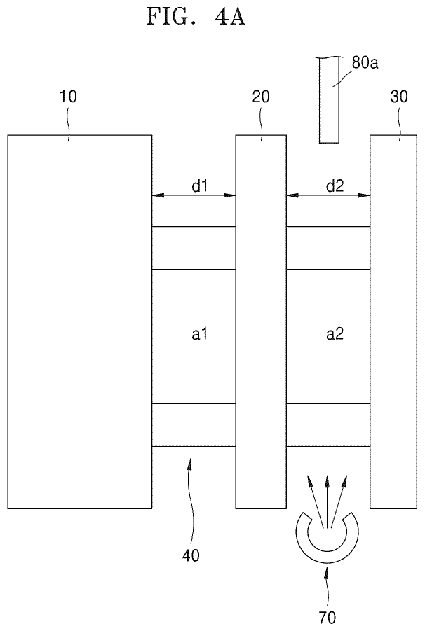

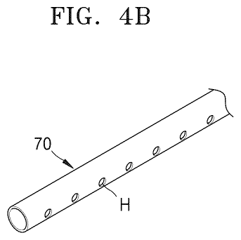

In an example, the first preset distance d1 may be greater than the second preset distance d2. As a result, for example, when refrigerant is introduced into the second space a2 as shown in FIG. 4A, loss of a heating temperature of the wall of the chamber 10 may be minimized.

Although FIG. 3 shows only two insulating plates, the disclosure is not limited thereto, and three or more insulating plates may be arranged to shield heat of the chamber 10.

FIG. 4A is a cross-sectional view of a heat shielding device according to further embodiments.

The substrate processing device may further include a refrigerant supplier 70 for supplying refrigerant to the first space a1 and/or the second space a2 in order to maximize heat shielding efficiency. It may be preferable that the refrigerant supplier 70 supplies refrigerant to the second space a2 rather than the first space a1. The second space a2 may have a lower temperature than the first space a1 when refrigerant is supplied only to the second space a2 so that the heating temperature loss of the chamber 10 may be minimized and at the same time heat transmit to the outside may be blocked. The first preset distance d1 may be greater than the second preset distance d2 to reduce the loss of the heating temperature of the chamber 10 while increasing cooling efficiency of the second space a2.

In more detail, as shown in FIG. 4A, the substrate processing device may further include a refrigerant supplier 70 for supplying refrigerant to the second space a2. By supplying refrigerant to the second space a2 through the refrigerant supplier 70, heat shielding efficiency may be increased. In addition, to increase the heat shielding efficiency, the refrigerant supplier 70 may provide lower temperature refrigerant and/or increase the flow rate of refrigerant and/or provide pressurized refrigerant.

Although FIG. 4A shows that refrigerant is supplied only to the second space a2, the refrigerant may be supplied to at least one of the first space a1 and the second space a2, as described later below.

FIG. 4B shows an example of the refrigerant supplier 70. As shown in FIG. 4B, the refrigerant supplier 70 may be in the form of a tube and may include a plurality of holes H for supplying refrigerant. By adjusting the size, the number, and the like of the holes H of the refrigerant supplier, the refrigerant supplier may provide refrigerant with a suitable flow rate and/or pressure. The refrigerant may be fluid, in particular gas. Although FIG. 4B shows a tube-type refrigerant supplier, the disclosure is not limited thereto. For example, the refrigerant supplier may be a fan or a corresponding device.

Referring again to FIG. 4A, the substrate processing device may further include a suction unit 80a for sucking gas inside the second space a2. The suction unit 80a may be installed to be in fluid communication with the second space a2 and may suck refrigerant (e.g., gas) supplied to the second space a2 through the refrigerant supplier 70 and discharge the refrigerant to the outside. The suction unit 80a may be, for example, a pipe.

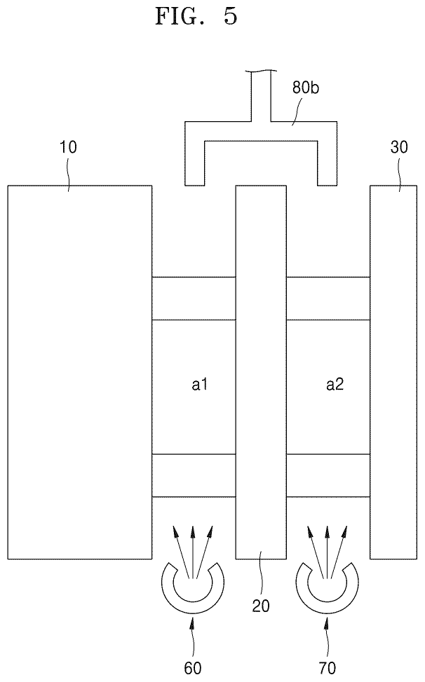

FIG. 5 schematically shows a cross-sectional view of a heat shielding device of a substrate processing device according to further embodiments. The heat shielding device of the substrate processing device according to the embodiments may be a modification of the heat shielding device according to the above-described embodiments. Hereinafter, repeated descriptions of the embodiments will not be given herein.

Referring to FIG. 5, the substrate processing device may further include an additional refrigerant supplier 60 for supplying refrigerant to the first space a1. By additionally supplying refrigerant to the first space a1 through the refrigerant supplier 60, heat shielding efficiency may be increased.

It is preferable that the temperature of the second space a2 is lower than the temperature of the first space a1 so as to minimize loss of a heating temperature of the chamber 10 while shielding the heat from the chamber 10. To this end, the refrigerant supplier 70 and the additional refrigerant supplier 60 may control at least one of a temperature and a flow rate of the refrigerant such that the temperature of the second space a2 is lower than the temperature of the first space a1.

The substrate processing device may further include a suction unit 80b for sucking gas in the first space a1 and the second space a2. The suction unit 80b may be installed to be in fluid communication with the first space a1 and the second space a2 and may suck refrigerant supplied to the first space a1 through the additional refrigerant supplier 60 and refrigerant supplied to the second space a2 through the refrigerant supplier 70 and discharge the refrigerants to the outside.

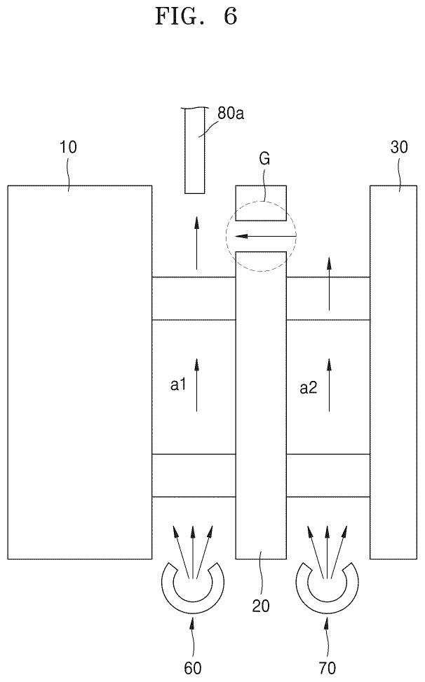

FIG. 6 schematically shows a cross-sectional view of a heat shielding device of a substrate processing device according to further embodiments. The heat shielding device of the substrate processing device according to the embodiments may be a modification of the heat shielding device according to the above-described embodiments. Hereinafter, repeated descriptions of the embodiments will not be given herein.

As shown in FIG. 6, there may be at least one gap G in the first insulating plate 20. The first space a1 and the second space a2 may communicate with each other through the at least one gap G. Since the first space a1 and the second space a2 communicate with each other, the suction unit 80a may be connected only to the first space a1.

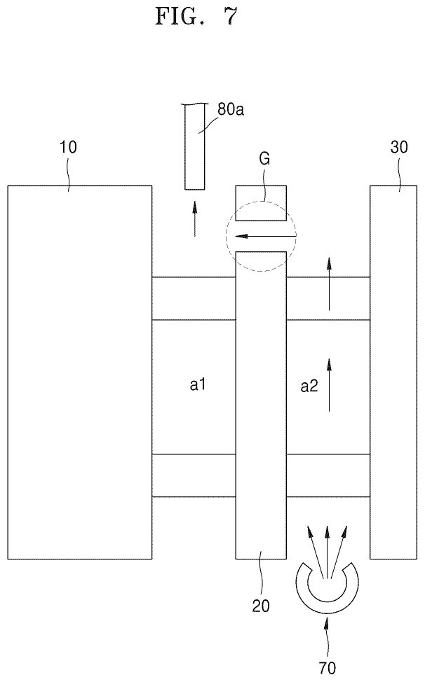

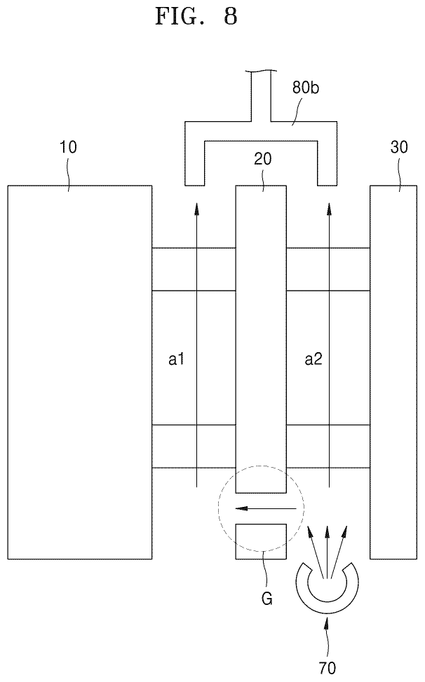

FIG. 7 shows a modification of the heat shielding device of FIG. 6. The heat shielding device of FIG. 7, unlike FIG. 6, does not include an additional refrigerant supplier 60. However, since the first space a1 and the second space a2 communicate with each other through the at least one gap G, refrigerant introduced into the second space a2 through the refrigerant supplier 70 will be introduced into the first space a1 through the at least one gap G so that the first space a1 may be cooled and exhausted through the suction unit 80a connected to the first space a1. In order to cool the first space a1 more evenly, as shown in FIG. 8, it is preferable that the at least one gap G is under the first insulating plate 20.

As such, the heat shielding device of FIG. 7 may cool both the first space a1 and the second space a2 with only the refrigerant supplier 70 without installing the additional refrigerant supplier 60. Since refrigerant supplied by the refrigerant supplier 70 flows into the first space a1 through the second space a2, a temperature of the first space a1 may be maintained higher than a temperature of the second space a2. As a result, heat may be effectively blocked at the same time while minimizing loss of a heating temperature of the chamber 10.

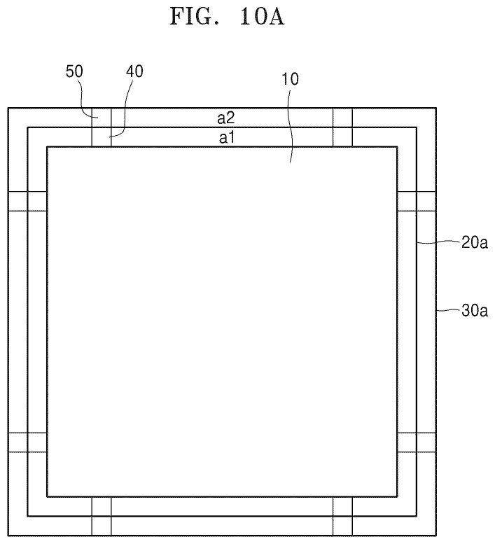

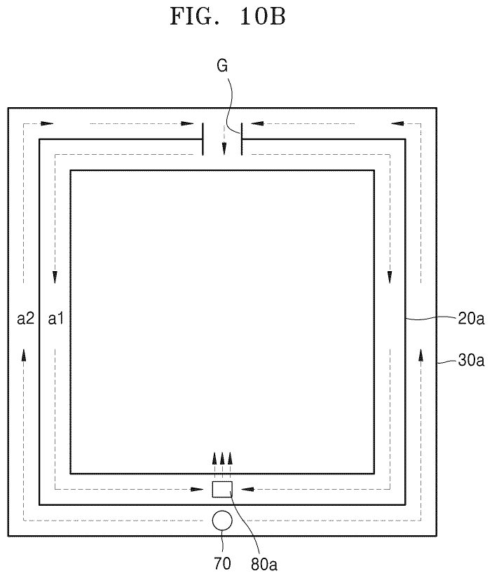

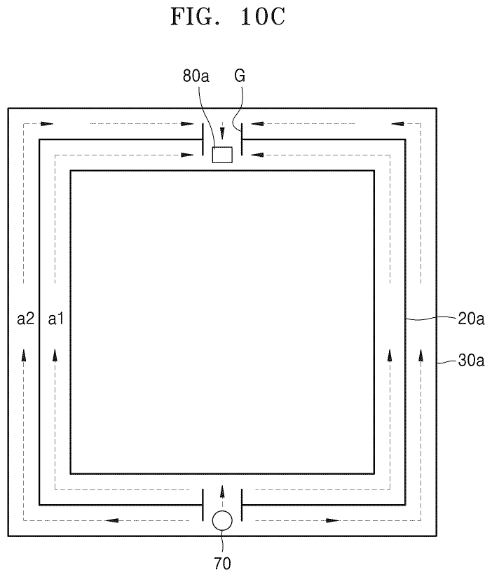

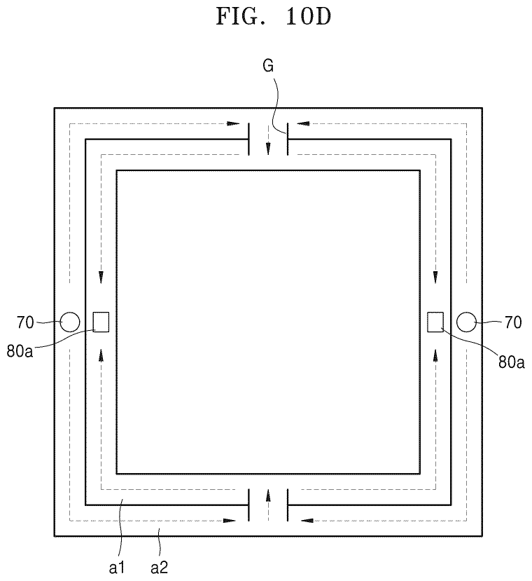

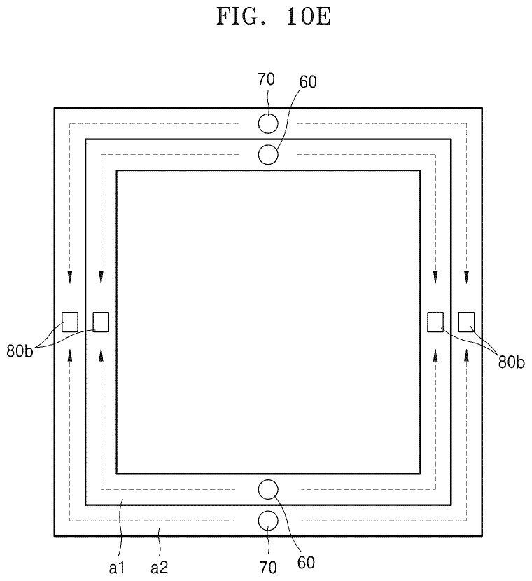

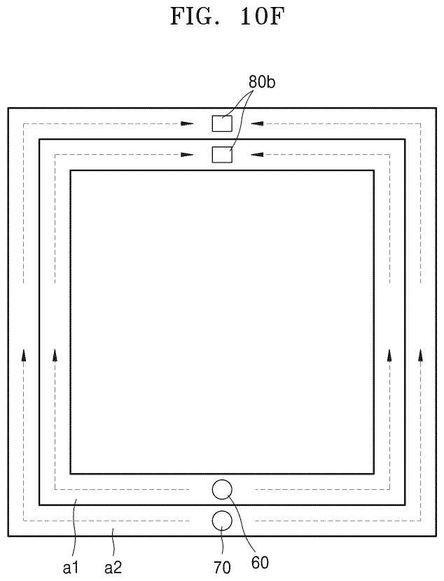

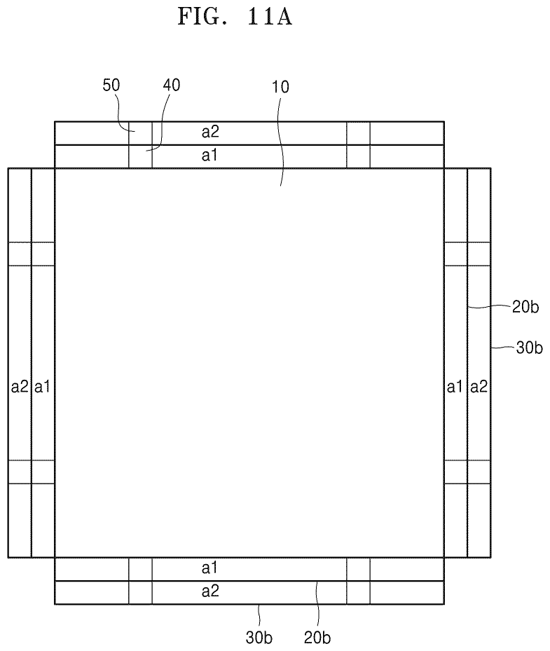

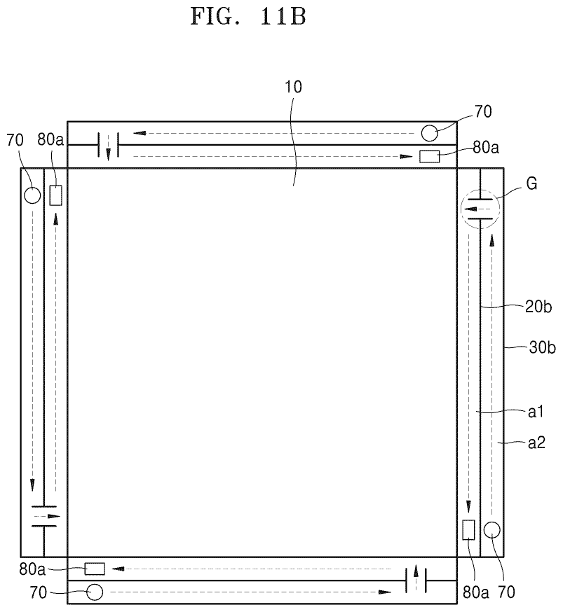

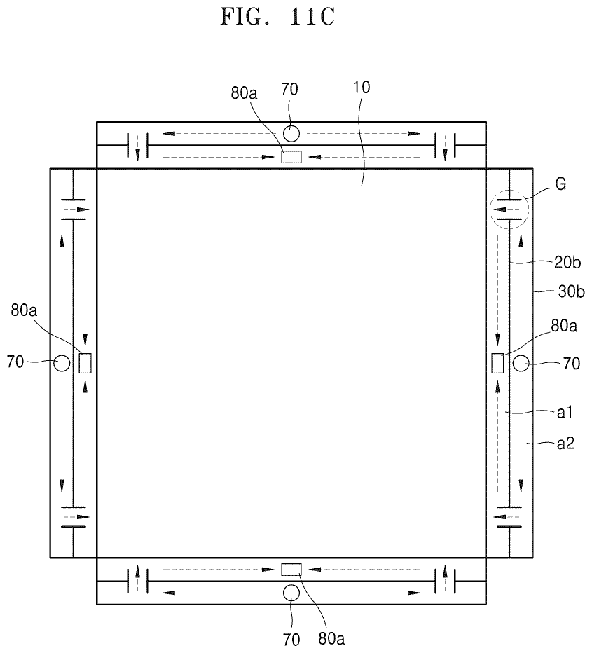

As described above with reference to FIGS. 3 to 8, according to other embodiments, the number and arrangement of insulating plates, refrigerant suppliers, suction units, gaps, and the like may be diversified considering cooling efficiency, temperature distribution, and the like, thereby improving the cooling efficiency. In this regard, a more detailed description will be made with reference to FIGS. 10A to 10F and FIGS. 11A to 11C.

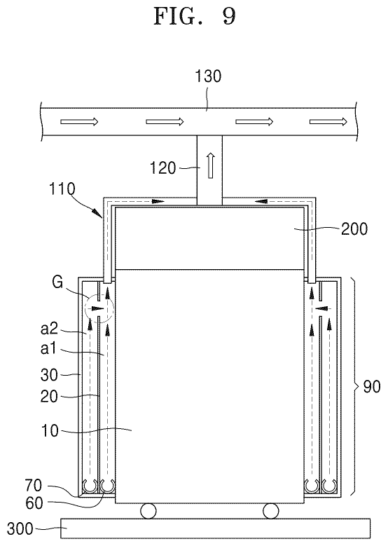

FIG. 9 schematically shows a cross-sectional view of a substrate processing device including a heat shielding device according to embodiments, the substrate processing device being installed in a substrate processing factory, e.g. FAB.

Referring to FIG. 9, the substrate processing device may include the chamber 10, a gas supplier 200, a heat shielding device 90, a suction unit 110, and exhausters 120 and 130. The substrate processing device may be fixedly mounted on a floor 300 in the substrate processing factory FAB.

The gas supplier 200 may be installed on one surface of the chamber 10. For example, the gas supplier may be implemented as a gas supply pipe (or gas jungle box), or a shower head-type assembly structure. In particular, the gas supplier in FIG. 9 may be configured as an integrated gas supplier (IGS), which is a gas supplier in a block form.

The gas supplier 200 may supply gas (e.g., source gas, reactive gas, purge gas, etc.) to the chamber 10 through the gas supply pipe.

The heat shielding device 90 may include the first insulating plate 20, the second insulating plate 30, the refrigerant supplier 70, and the additional refrigerant supplier 60. The gap G may be formed on the first insulating plate 20.

A specific description of each portion of the heat shielding device 90 has been described in detail with reference to FIGS. 3 to 8, and therefore will not be given herein.

Although FIG. 9 shows a cross-sectional view of the substrate processing device including the heat shielding device of FIG. 6, the disclosure is not limited thereto. For example, the heat shielding device of FIG. 7 may be installed instead of the heat shielding device of FIG. 6.

The substrate processing device may further include the suction unit 110. The suction unit 110 may be configured to suck fluid (e.g., refrigerant gas) filled in the first space a1 of the heat shielding device 90. Although the suction unit 110 of FIG. 9 is shown as the suction unit 80a of the above-described embodiments in FIG. 6, the disclosure is not limited thereto. For example, the suction unit 110 of FIG. 9 may be configured to suck fluid (e.g., refrigerant gas) filled in the first space a1 and the second space a2 like the suction unit 80b of FIG. 5.

The suction unit 110 may suck refrigerant supplied through the refrigerant suppliers 60 and 70 and discharge the refrigerant through the exhausters 120 and 130 connected to the suction unit 110.

In a further embodiment, the suction unit 110 may be configured to be disposed along an outer wall of the gas supplier 200 as shown in FIG. 9, thereby making it possible to configure a substrate processing device that is easier to maintain. In another embodiment, the suction unit 110 may be directly connected to the gas supplier 200 so that the refrigerant passes through the inside of the gas supplier 200 and may be discharged to the exhausters 120 and 130. This makes it possible to configure a substrate processing device that is simpler and easier to maintain.

An exhauster may include a first exhaust pipe 120 and a second exhaust pipe 130. The first exhaust pipe 120 may be connected to the suction unit 110, and the second exhaust pipe 130 may be connected to the first exhaust pipe 120. The first exhaust pipe 120 and/or the second exhaust pipe 130 may be some of utility facilities in the substrate processing factory FAB.

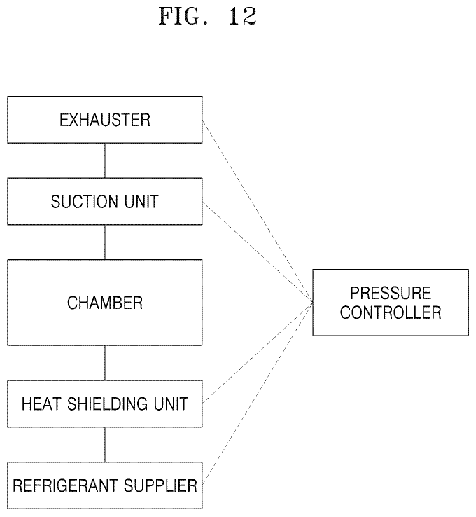

In order to facilitate the efficient flow of refrigerant and to facilitate exhaust from the first space a1 and/or the second space a2, it is preferable that the relationship of pressure of the heat shielding device 90>pressure of the suction unit>pressure of the exhauster is satisfied (i.e., P_{heat shielding device}>P_{suction unit}>P_{first exhaust pipe}>P_{second exhaust pipe}). In particular, in the embodiment of FIG. 9, it is preferable that the relationship of pressure of the second space a2>pressure of the first space a1>pressure of the suction unit 110>pressure of the exhausters 120 and 130 is maintained so that gas in the second space a2 may be exhausted smoothly through the suction unit 110 through the first space a1. By forming a pressure gradient in this way, gas flow of laminar flow may be maintained until refrigerant is introduced and exhausted. To maintain this pressure gradient, the substrate processing device may further include a pressure gauge (not shown) and/or a pressure controller (see FIG. 12). The pressure gauge may be installed in the first space a1, the second space a2, the suction unit 110, the exhausters 120 and 130, or the like and may measure the pressure of each of them. The pressure controller may monitor the pressures of the first space a1, the second space a2, the suction unit 110, and the exhausters 120 and 130 directly or through the pressure gauge in real time and may control pressures of some devices to maintain the above-described pressure relationship. For example, the pressure controller may adjust the pressure of the first space a1 and/or the second space a2 by adjusting a flow rate of the refrigerant supplier, and/or may adjust the pressure of the suction unit 110 by adjusting a suction pressure regulating valve (not shown) of the suction unit 110, and/or may adjust the pressure of the exhausters 120 and 130 by adjusting a pressure regulating valve (not shown) of the exhausters 120 and 130. FIG. 12 shows a pressure controller for monitoring and/or controlling the pressure of a refrigerant supplier, the pressure of a heat shielding unit (i.e., the pressure of the first space a1 and the second space a2), the pressure of a suction unit, and the pressure of an exhauster.

In a further embodiment, the exhausters 120 and 130 may be connected to the gas supplier 200. The exhausters 120 and 130 may keep the gas supplier 200 at a certain temperature by exhausting the inside of the gas supplier 200, thereby reducing the risk of fire, toxic gas leakage, and the like.

In order to facilitate the exhaust of the gas supplier 200, it is preferable that the relationship of pressure of the gas supplier 200>pressure of the suction unit 110>pressure of the exhausters 120 and 130 is maintained (that is, P_{gas supplier}>P_{suction unit}>P_{first exhaust pipe}>P_{second exhaust pipe}).

To maintain this pressure gradient, the substrate processing device may further include a pressure gauge (not shown) and/or a pressure controller (not shown). The pressure gauge may be installed in the gas supplier 200, the suction unit 110, the exhausters 120 and 130, or the like and may measure the pressure of each of them. The pressure controller may monitor the pressures of the gas supplier 200, the suction unit 110, the exhausters 120 and 130 directly or through the pressure gauge or in real time and may control pressures of some devices to maintain the above-described pressure relationship. For example, the pressure controller may adjust the pressure of the gas supplier 200, and/or may adjust the pressure of the suction unit 110 by adjusting a suction pressure regulating valve of the suction unit 110, and/or may adjust the pressure of the exhausters 120 and 130 by adjusting a pressure regulating valve of the exhausters 120 and 130. FIG. 12 shows a pressure controller for monitoring and/or controlling the pressure of a gas supplier, the pressure of a heat shielding unit (i.e., the pressure of the first space a1 and the second space a2), the pressure of a suction unit, and the pressure of an exhauster.

FIG. 10A schematically shows a top view of a heat shielding device according to embodiments. The heat shielding device of the substrate processing device according to the embodiments may be a modification of the heat shielding device according to the above-described embodiments. Hereinafter, repeated descriptions of the embodiments will not be given herein.

The substrate processing device may include the chamber 10, a first insulating plate 20a apart from the chamber 10 and surrounding the chamber 10, and a second insulating plate 30a apart from the first insulating plate 20a and surrounding the first insulating plate 20a.

The first insulating plate 20a may be apart from the outer wall of the chamber 10 by at least one first support 40. The second insulating plate 30a may be apart from the first insulating plate 20a by at least one second support 50.

The first insulating plate 20a and the chamber 10 are apart from each other so that the first space a1 may be between the first insulating plate 20a and the chamber 10. The first insulating plate 20a and the second insulating plate 30a are apart from each other so that the second space a2 may be between the first insulating plate 20a and the second insulating plate 30a. In a case of the heat shielding device of FIG. 10A, the first space a1 and the second space a2 continuously surround the chamber 10. However, the disclosure is not limited thereto. For example, as shown in FIGS. 11A to 11C, insulating plates may be separately provided for each outer wall of the chamber 10 to shield heat from the chamber 10 to the outside.

As described above, by separating the first insulating plate from the wall of the chamber 10 instead of attaching the first insulating plate to the wall of the chamber 10, the heat of the chamber 10 may be prevented from being directly transmitted to the first insulating plate. In addition, two gas insulating layers (spaces) may be formed to minimize thermal conductivity from the chamber. Thus, effective heat shielding may be achieved.

Further, the substrate processing device further includes a refrigerant supplier that communicates with the first space a1 or the second space a2, so that the heat conductivity from the chamber may be further minimized. In particular, in the case of the heat shielding device of FIG. 10A, since the first space a1 and the second space a2 continuously surround the chamber, refrigerant may be introduced into the entire first space a1 and/or the entire second space a2 by only one refrigerant supplier and the gas in the entire first space a1 and/or the entire second space a2 may be sucked by only one suction port. This will be described later below with reference to FIGS. 10B to 10F.

FIGS. 10B to 10F schematically show various flow directions of refrigerant flowing in a heat shielding device according to other embodiments. According to FIGS. 10B to 10F, various refrigerant flows may be realized by changing the number and arrangement of insulating plates, refrigerant suppliers, suction units, gaps, and the like, thereby improving cooling efficiency. The heat shielding device according to these embodiments may be a variation of the heat shielding device of FIG. 10A. Hereinafter, repeated descriptions of the embodiments will not be given herein.

As a first example, the heat shielding device may include, as shown in FIG. 10B, the suction unit 80a connected to the first space a1 and the refrigerant supplier 70 communicating with the second space a2. One gap G may be formed in the first insulating plate 20a and the first space a1 and the second space a2 may communicate with each other through the gap G.

The gap G may be located opposite the refrigerant supplier 70 with respect to the chamber 10. Thus, refrigerant may flow symmetrically in the second space a2 and temperature distribution in the second space a2 may be symmetrical and/or uniform. This will be described later below.

The suction unit 80a may suck gas in the first space a1. The suction unit 80a may be located opposite the at least one gap G with respect to the chamber 10. Thus, refrigerant may flow symmetrically in the first space a1 and temperature distribution in the first space a1 may be symmetrical and/or uniform. This will be described later below.

In this example, refrigerant first flows into the second space a2 through the refrigerant supplier 70. The refrigerant flows simultaneously in the clockwise/counterclockwise direction in the second space a2 along the first insulating plate 20a and a second insulating plate 30a. The refrigerant flow flowing in the clockwise/counterclockwise direction in the second space a2 flows into the first space a1 through the gap G formed in the first insulating plate 20a. The refrigerant flowing into the first space a1 flows respectively and simultaneously in the clockwise/counterclockwise direction in the first space a1 along an outer wall of the first insulating plate 20a and the chamber 10. The refrigerant flowing in different directions in the first space a1 may be sucked by the suction unit 80a.

According to this example, since the refrigerant flows symmetrically, simultaneously and uniformly in both the first space a1 and the second space a2, uneven cooling may be prevented. Further, since the refrigerant flows into the first space a1 through the second space a2, a temperature of the refrigerant flowing into the first space a1 will be higher than a temperature of the refrigerant flowing into the second space a2. Thus, it is possible to reduce the loss of a heating temperature of a chamber wall while shielding heat from the chamber wall to the outside. However, a difference between the temperatures of the refrigerants flowing into the first space a1 and the second space a2 may be diversified by increasing a flow rate of the refrigerant flowing into the second space a2, and/or increasing the number of gaps formed in the first insulating plate 20a, and/or increasing the number of refrigerant inlets.

Furthermore, in this example, the entire periphery of the chamber 10 is uniformly cooled by using only one refrigerant supplier 70, one suction unit 80a, and one gap G. This is possible because the first space a1 and the second space a2 continuously surround the chamber and the first space a1 and the second space a2 communicate with each other through the gap G. That is, the first insulating plate 20a continuously surrounds the chamber 10 and the second insulating plate 30a continuously surrounds the first insulating plate 20a, so that the number of parts necessary for cooling the periphery of the chamber may be reduced, thereby reducing the cost of manufacturing and installing the heat shielding device.

As a second example, the heat shielding device may include, as shown in FIG. 10C, the suction unit 80a connected to the first space a1 and the refrigerant supplier 70 communicating with the second space a2. Two gaps G may be formed in the first insulating plate 20a and the first space a1 and the second space a2 may communicate with each other through the gap G.

Unlike FIG. 10B where only one gap G is formed, two gaps G are formed in the first insulating plate 20a of FIG. 10C. However, in a case of the heat shielding device shown in FIG. 10C, refrigerant does not flow into the first space a1 through the second space a2 but flows into the first space a1 and the second space a2 through the refrigerant supplier 70 at the same time. Therefore, a temperature of the refrigerant flowing into the first space a1 and a temperature of the refrigerant flowing into the second space a2 may be substantially equal to each other. Thus, in order to minimize the loss of the heating temperature of the chamber wall while shielding heat from the chamber wall to the outside, the heat shielding device of FIG. 10B is more advantageous than the heat shielding device of FIG. 10C.

As a third example, the heat shielding device may include, as shown in FIGS. 10D and 10E, two or more gas suppliers 60 and 70 symmetrically arranged in at least one of the first space a1 and the second space a2, and two or more suction units 80a and 80b symmetrically arranged in at least one of the first space a1 and the second space a2. FIG. 10D shows an example in which the gap G is formed in the first insulating plate 20a and FIG. 10E shows an example in which the gap G is not formed in the first insulating plate 20a.

Since the gas suppliers 60 and 70 and the suction units 80a and 80b are symmetrically arranged, the flow of refrigerant in the first space a1 and the second space a2 is symmetrical, so that the periphery of the chamber 10 may be cooled symmetrically and uniformly.

Finally, FIG. 10F shows a case where refrigerant flows symmetrically in the first space a1 and the second space a2 although the gas suppliers 60 and 70 and the suction units 80a and 80b are not symmetrically arranged.

FIG. 11A schematically shows a top view of a heat shielding device according to other embodiments. The heat shielding device of the substrate processing device according to the embodiments may be a modification of the heat shielding device according to the above-described embodiments. Hereinafter, repeated descriptions of the embodiments will not be given herein.

The substrate processing device may include the chamber 10, a plurality of first insulating plates 20b, and a plurality of second insulating plates 30b.

Each of the plurality of first insulating plates 20b may form the first space a1 together with one outer wall of the chamber 10. A plurality of first spaces a1 may be formed by the plurality of first insulating plates 20b and the outer wall of the chamber 10. The plurality of first spaces a1 may be apart from each other.

Each of the plurality of second insulating plates 30b may form the second space a2 together with one of the plurality of first insulating plates 20b. A plurality of second spaces a2 may be formed by the plurality of first insulating plates 20b and the plurality of second insulating plates 30b. The plurality of second spaces a2 may be apart from each other. Unlike the heat shielding device of FIG. 10A, in the heat shielding device of FIG. 11A, the first space a1 and the second space a2 are not continuously formed along the outer wall of the chamber 10.

The two gas insulating layers a1 and a2 are formed between the outer wall and the outer space of the chamber using the first insulating plates 20b and the second insulating plates 30b so that heat radiated to the outside from the chamber wall heated to a high temperature may be blocked. This may reduce heat loss and power consumed when heating the chamber to a certain temperature, and may reduce safety problems such as burning of an operator.

Further, the substrate processing device further includes a refrigerant supplier that communicates with the first space a1 or the second space a2, so that the heat conductivity from the chamber may be further minimized. In particular, the substrate processing device may further include a refrigerant supplier communicating with the second space a2 so as to minimize the loss of a heating temperature of the chamber 10 while at the same time shielding heat to the outside. However, unlike the heat shielding device of FIG. 10A, in the case of FIG. 11A, since the plurality of second spaces a2 are apart from each other, at least one refrigerant supplier needs to be connected to each of the second spaces a2 in order to supply refrigerant to all the second spaces a2. This will be described later below with reference to FIGS. 11B and 11C.

FIGS. 11B and 11C schematically show various flow directions of refrigerant flowing in a heat shielding device according to other embodiments. Referring FIGS. 11B and 11C, various refrigerant flows may be realized by changing the number and arrangement of insulating plates, refrigerant suppliers, suction units, gaps, and the like, thereby improving cooling efficiency. The heat shielding device according to these embodiments may be a variation of the heat shielding device of FIG. 11A. Hereinafter, repeated descriptions of the embodiments will not be given herein.

The heat shielding device may include a plurality of suction units 80a connected to the respective first spaces a1 and a plurality of refrigerant suppliers 70 communicating with the respective second spaces a2 as shown in FIGS. 11B and 11C. At least one gap G may be formed in each of the first insulating plates 20b. Each of the first spaces a1 may communicate with the corresponding second space a2 through the gap G.

As shown in FIGS. 11B and 11C, the plurality of suction units 80a, the plurality of refrigerant suppliers 70, and a plurality of gaps G may be symmetrically arranged with respect to the chamber 10 so that temperature distribution around the outside of the chamber 10 may be symmetrical and/or uniform.

Unlike the heat shielding device of FIG. 10B, which is capable of cooling the entire second space a2 using only one refrigerant supplier, the heat shielding device of FIGS. 11B and 11C requires at least four refrigerant suppliers to cool the entire second space a2. This is because the plurality of second spaces a2 are apart from each other in the case of the heat shielding device of FIGS. 11B and 11C. Thus, although the configurations of FIGS. 11B and 11C may require more devices (e.g., a refrigerant supplier, a suction unit, etc.) than the configuration of FIG. 10B, there is an advantage that a temperature of each of the second spaces a2 and a refrigerant flow rate may be individually and more precisely controlled.

A heat shielding device according to embodiments may block heat from a chamber wall heated to a high temperature during a substrate processing process, thereby reducing heat loss and power consumed when a chamber is heated to a certain temperature. Further, the heat shielding device may reduce safety problems such as burning of an operator. In a further embodiment, cooling efficiency may be improved by varying temperatures and flow rates of a refrigerant supplier, a suction unit, and refrigerant of the heat shielding device according to the embodiments. In another further embodiment, the heat shielding device may facilitate the efficient flow of refrigerant by sequentially changing refrigerant flow pressures at the refrigerant supplier, the suction unit, and an exhauster, that is, by forming a pressure gradient.

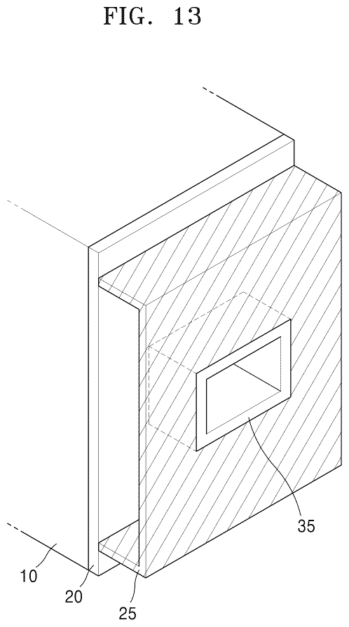

FIG. 13 schematically shows a substrate processing device according to embodiments of the inventive concept. The substrate processing device according to the embodiments may be a variation of the substrate processing device according to the above-described embodiments. In addition, the substrate processing device according to the embodiments may introduce configurations of a heat shielding device according to the above-described embodiments. Hereinafter, repeated descriptions of the embodiments will not be given herein.

Referring to FIG. 13, the substrate processing device may include a chamber 10, a metal plate 25 disposed on an outer wall of the chamber 10, and a first insulating plate 20 disposed between the outer wall of the chamber 10 and the metal plate 25.

The chamber 10 may be configured to accommodate a substrate therein and perform a processing process on the substrate. For example, the chamber 10 may be a reaction chamber including a reaction space. To receive a substrate into the chamber 10, the chamber 10 may include a substrate movement channel 35. The substrate movement channel 35 may be formed to pass through the first insulating plate 20 and the metal plate 25.

The chamber 10 may be configured to perform a high temperature process. For example, the chamber 10 may include a heating block configured to heat the substrate while supporting it, and the temperature of the heating block may be heated to about 500 degrees Celsius or more during the high temperature process. During the high temperature process, the reaction space of chamber 10 may be isolated from the substrate transfer channel 35.

After the high temperature process, the substrate may be transferred to another chamber 10 (e.g. a transfer chamber), and for this purpose, the reaction space of the chamber 10 and the substrate transfer channel 35 may communicate with each other. At this time, thermal energy remaining in the reaction space may be transmitted into the substrate transfer channel 35. The thermal energy transmitted into the substrate transfer channel 35 may cause a problem that adversely affects components 10 (e.g. the transfer chamber) connected to the chamber. Also, the thermal energy transmitted into an adjacent chamber may affect the quality of the process carried out therein.

A substrate processing device according to embodiments by the inventive concept aims to solve this problem, and it introduces a first insulating plate 20 and a metal plate 25 having heat resistance to the outer wall of the chamber 10. The first insulating plate 20 and the metal plate 25 of low thermal conductivity may be disposed around the substrate transfer channel 35, and with this arrangement, transmission of thermal energy remaining in the reaction space to other components can be reduced.

The first insulating plate 20 may be implemented as a composite material having high mechanical strength, excellent in dimensional stability, impact resistance, and durability as well as excellent thermal insulation property. To this end, the first insulating plate 20 may include glass fiber and a thermosetting resin. Specifically, the first insulating plate 20 may be implemented as a structure in which a plurality of layers including glass fibers and a thermosetting resin are stacked. In some embodiments, the thermal conductivity of the first insulating plate 20 may be less than 0.3 W/mK.

In some embodiments according to the inventive concept, the metal plate 25 having heat resistance properties may have a thermal conductivity of less than 30 W/mK. The metal plate 25 having such a low thermal conductivity of less than 30 W/mK may perform a function of blocking heat. In some embodiments, one surface of the metal plate 25 may be polished to perform a heat reflecting function. In an alternative embodiment, a metal layer (e.g., an aluminum layer or a chromium layer) having a high reflectance may be formed on one surface of the metal plate 25.

As a metal material having a thermal conductivity of less than 30 W/mK, stainless steel containing at least 12 wt % of chromium can be used. For example, martensitic stainless steel (e.g., STS410) containing 13 wt % of chromium may have a thermal conductivity of 24.9 W/mK, and thus the martensitic stainless steel can be used as the metal plate 25 having heat resistance properties of the present invention.

In more preferred embodiments, the metal plate 25 having heat resistance properties of the present invention may include an austenitic stainless steel (e.g. STS304) having higher durability in high temperature processes. For example, a metal plate 25 made of 18Cr-8Ni based stainless steel containing 18% of Cr and 8% of Ni may be disposed to surround an outer wall area of the chamber 10 except for the substrate transfer channel 35. Such austenite-based stainless steel is useful in that it not only has high heat resistance properties but also suppresses formation of pin holes that may occur in forming a heat reflection layer thereon.

In additional embodiments, as the heat reflection layer, a chromium layer (not shown) may be formed on a surface of the metal plate 25 facing the first insulating plate 20. Specifically, the metal plate 25 may include a flat portion and a bending portion, and the chrome layer may be formed on a surface of the flat portion facing the first insulating plate 20. In a further embodiment, the chromium layer may also be formed on one surface of the bending portion.

For example, the chromium layer may be implemented through a chromium plating process on the metal plate 25. Specifically, in some embodiments, the chromium layer may directly contact a surface of a remaining metal plate 25 by the plating process. For example, when the metal plate 25 includes 18Cr-8Ni-based stainless steel, a surface of the 18Cr-8Ni-based stainless steel facing the first insulating plate 20 may directly contact the chromium layer.

In another embodiment, a copper layer or a nickel layer may be formed between the chromium layer and the surface of the metal plate 25. In an alternative embodiment, the metal plate 25 may include a plurality of sputtering layers on a surface facing the first insulating plate 20, and each of the sputtering layers may include at least one of nickel and chromium.

The first insulating plate 20 and the metal plate 25 may be formed to surround at least a portion of the substrate transfer channel 35 so that transmission of thermal energy remaining in the reaction space to other components can be reduced. Specifically, each of the first insulating plate 20 and the metal plate 25 may include a through hole having a shape corresponding to the cross section of the substrate transfer channel 35. Through this, the substrate transfer channel 35 may be formed to pass through the first insulating plate 20 and the metal plate 25.

In one embodiment, the through hole of the metal plate 25 may contact an outer surface of the substrate transfer channel 35. For example, when the cross-sectional shape of the substrate transfer channel 35 is rectangular, the through hole of the metal plate 25 may also be rectangular, and thus each of the four surfaces of the through hole may contact four outer surfaces of the substrate transfer channel 35 respectively.

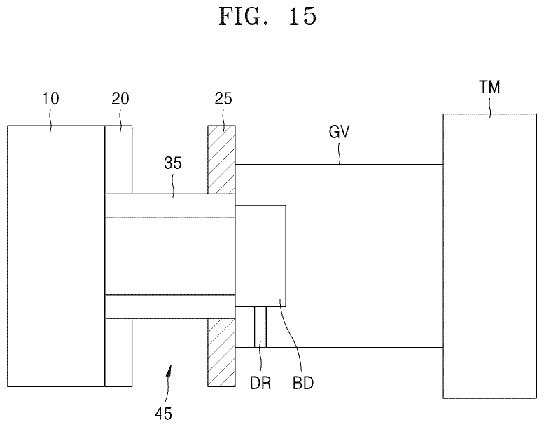

As the metal plate 25 and the substrate movement channel 35 contact each other in this way, diffusion of thermal energy transmitted from the reaction space through the substrate transfer channel 35 may be partially blocked by the metal plate 25. In particular, a heat diffusion channel (e.g. 45 in FIG. 15) may be formed through a space between the first insulating plate 20 and the metal plate 25, and the heat energy transmitted through the substrate transfer channel 35 can be distributed along the heat diffusion channel. In other words, the diffusion direction of the thermal energy may be converted from a first direction along the substrate transfer channel 35 to a second direction along the thermal diffusion channel extending between the first insulating plate 20 and the metal plate 25.

In particular, by forming a heat reflection layer (for example, a chromium layer) performing a heat reflection function on the metal plate 25, at least a portion of the thermal energy that diffuses around a first direction through the substrate transfer channel 35 have a changed diffusion direction. The thermal energy with such a changed diffusion direction can move along the heat diffusion channel between the first insulating plate 20 and the metal plate 25.

In some embodiments, the reflectance of the heat reflection layer may be greater than that of the metal plate 25. For example, the heat reflection layer may be implemented as an aluminum layer or a chromium layer. Since the metal plate 25 having such a heat reflection layer has lower thermal conductivity, is relatively more resistant to corrosion, has no magnetism, and is resistant to impact, compared with a single heat reflection layer (i.e. a single aluminum layer or a single chromium layer). Accordingly, the metal plate 25 having a separate hear reflection layer may be suitable for substrate processing devices.

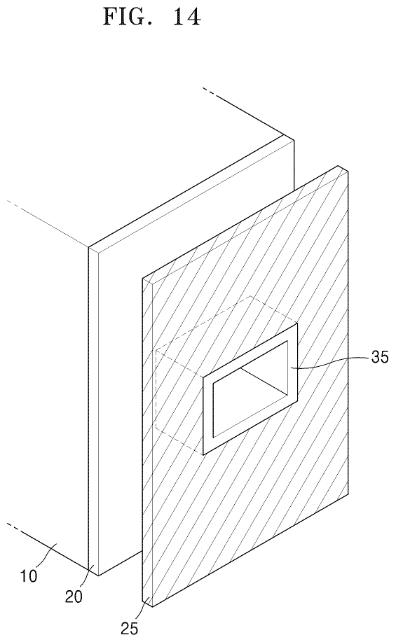

FIG. 14 schematically shows a substrate processing device according to embodiments of the inventive concept. The substrate processing device according to the embodiments may be a variation of the substrate processing device according to the above-described embodiments. In addition, the substrate processing device according to the embodiments may introduce configurations of a heat shielding device according to the above-described embodiments. Hereinafter, repeated descriptions of the embodiments will not be given herein.

Referring to FIG. 14, a substrate transfer channel 35 is formed between the first insulating plate 20 and the metal plate 25, and the substrate transfer channel 35 may extend in a first direction (e.g. a horizontal direction). Accordingly, the substrate may move in the first direction through the substrate transfer channel 35. As described above, the substrate transfer channel 35 may extend passing through the first insulating plate 20 and the metal plate 25, and in some embodiments, at least a portion of the substrate transfer channel 35 may contact the first insulating plate 20. and the metal plate 25.

The first insulating plate 20 and the metal plate 25 may extend in a second direction (e.g. a vertical direction) different from the first direction. The metal plate 25 may form a heat diffusion channel together with the first insulating plate 20. For example, by the metal plate 25 reflecting at least a portion of the thermal energy transmitted and diffused along the substrate transfer channel 35, the reflected thermal energy may be diffused through a space between the metal plate 25 and the first insulating plate 20.

In contrast to the embodiment of FIG. 13, the metal plate 25 may be formed without a separate bending portion. The metal plate 25 of FIG. 13 may function as a portion of the cover of the substrate processing device, and thus a part of the metal plate 25 may be bent for safety of workers. Since this end portion (i.e. bending portion) of the metal plate 25 thus formed has higher thermal conductivity than air, radiation and conduction of thermal energy transmitted through the substrate transfer channel 35 through the bending portion may be promoted. Furthermore, the bending portion may prevent thermal energy reflected by the metal plate 25 from being diffused through the heat diffusion channel.

Therefore, the inventor removed the bending portion of the metal plate 25 that increases heat radiation or heat conduction and hinders the thermal diffusion function. That is, in order that the size of the air gap formed in the space between the first insulating plate 20 and the metal plate 25 may be increased, and that the thermal energy transmitted through the substrate transfer channel 35 is diffused along the thermal diffusion channel without a separate obstacle, the metal plate 25 may be configured to have no bending portion around the substrate movement channel 35 of the metal plate 25.

FIG. 15 schematically shows a substrate processing device according to embodiments of the inventive concept. The substrate processing device according to the embodiments may further comprise a gate valve GV and a transfer chamber TM in addition to the substrate processing device according to the above-described embodiments. In addition, the substrate processing device according to the embodiments may introduce configurations of a heat shielding device according to the above-described embodiments. Hereinafter, repeated descriptions of the embodiments will not be given herein.

Referring to FIG. 15, the gate valve GV connected to the substrate processing device may be connected to the substrate transfer channel 35. The chamber 10 allows substrates to enter and exit through the substrate transfer channel 35, but the chamber 10 may usually be kept in a high-temperature isolation state during its processing. For such operations, the substrate transfer channel 35 may be open or closed, which may be implemented through the gate valve GV.

The gate valve GV may include a body unit BD and a driving unit DR. The body unit BD may close the substrate transfer channel 35 in a first state and open the substrate transfer channel 35 in a second state. The driving unit DR may drive the body unit BD so that the body unit BD is in the first state or the second state.

For example, before performing the substrate processing, the drive unit DR may drive the body unit BD so that the body unit BD is in the second state, so that the substrate transfer channel 35 becomes open. At this time, the substrate may be transferred from the transfer chamber TM to the gate valve GV, and the substrate may be further transferred to the chamber 10 through the open substrate transfer channel 35.

Thereafter, in order to perform the substrate processing, the driving unit DR may drive the body unit BD so that the body unit BD is in a first state, and thus the substrate transfer channel 35 may become closed. Accordingly, the chamber 10 may perform a high-temperature process on the substrate while maintaining an isolated state (e.g. a vacuum state).

After the substrate processing process is performed, the drive unit DR may drive the body unit BD so that the body unit BD returns to the second state, and thus the substrate transfer channel 35 may be opened. At this time, the substrate may be transferred from the chamber 10 to the gate valve GV through the substrate transfer channel 35, and the substrate may be transferred to the transfer chamber TM from the gate valve GV. The substrate transferred to the transfer chamber TM may be transferred to another chamber for a subsequent process or the like.

In some embodiments, at least a portion of the gate valve GV may include an additional metal plate (not shown) having heat resistance properties. In one embodiment, the additional metal plate (not shown) may have a thermal conductivity of less than 30 W/mK. The heat-resistant additional metal plate (not shown) may prevent heat energy generated during the substrate process of the chamber 10 from being transmitted to the gate valve GV.

In some embodiments, the body portion BD of the gate valve GV may be formed of an additional metal plate (not shown). In another embodiment, at least a portion of the body portion BD of the gate valve GV may be formed as an additional metal plate (not shown). For example, an additional metal plate (not shown) may be formed on a surface of a portion of the body BD that is exposed to the outside (i.e. a surface facing the chamber 10). An additional metal plate (not shown) formed on the outer region of the body portion BD may function to block transmission of thermal energy diffused through the substrate transfer channel 35.

In some embodiments, an additional metal plate (not shown) of the gate valve GV may be formed of the same material as the metal plate 25 adjacent to the chamber 10. For example, a heat reflection layer may be formed on an outer surface (i.e. a surface facing the substrate transfer channel 35) of the additional metal plate (not shown) of the gate valve GV. Therefore, while the gate valve GV is closed and the high-temperature process is performed in the chamber 10, the thermal energy generated in the chamber 10 and transmitted through the substrate transfer channel 35 may be blocked by the heat reflection layer of the additional metal plate (not shown) of the gate valve GV. As a result, heat transmission from the chamber 10 to the gate valve GV and the transfer chamber TM can be reduced.

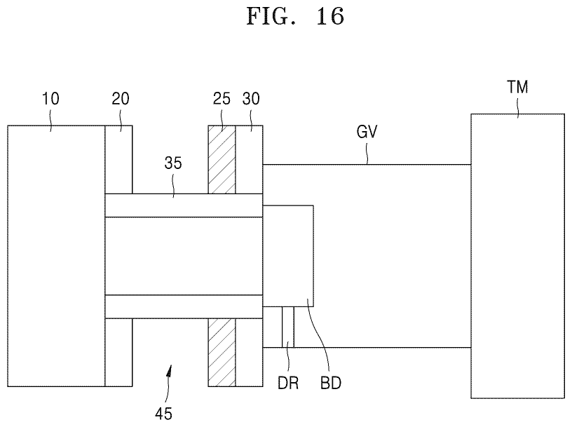

FIG. 16 schematically shows a substrate processing device according to embodiments of the inventive concept. The substrate processing device according to the embodiments may be a variation of the substrate processing device according to the above-described embodiments. In addition, the substrate processing device according to the embodiments may introduce configurations of a heat shielding device according to the above-described embodiments. Hereinafter, repeated descriptions of the embodiments will not be given herein.

Referring to FIG. 16, the substrate processing device may include a second insulating plate 30 disposed to be spaced apart from the first insulating plate 20. The second insulating plate 30 may be disposed outside the metal plate 25 and function as an outer cover of the substrate processing device. The second insulating plate 30 may have a lower thermal conductivity than the metal plate 25 (e.g. thermal conductivity of less than 0.3 W/mK). For example, the second insulating plate 30 may include polycarbonate.

The second insulating plate 30 may contact the gate valve GV as an outer cover. In addition, the second insulating plate 30 may include a through hole through which the substrate transfer channel 35 passes through the second insulating plate 30. The through hole of the second insulating plate 30 may contact the surface of the substrate transfer channel 35. For example, an inner circumferential surface of the through hole of second insulating plate 30 may contact an outer circumferential surface of the substrate transfer channel 35.

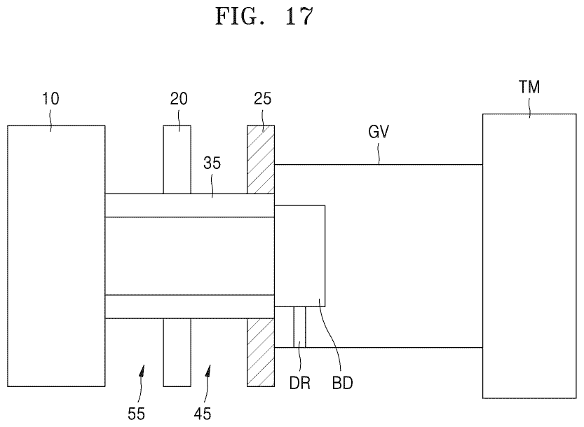

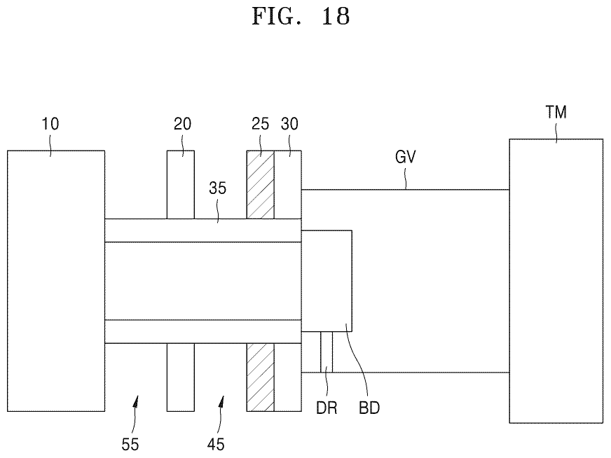

Although an embodiment in which the chamber 10 and the first insulating plate 20 are in contact with each other is shown in FIGS. 15 and 16, the present invention is not limited thereto, and as shown in FIGS. 17 and 18, the chamber 10 and the first insulating plate 20 may be spaced apart from each other. In this case, an additional heat diffusion channel 55 may be formed by the chamber 10 and the first insulating plate 20 in addition to the heat diffusion channel 45 formed by the first insulating plate 20 and the metal plate 25. In some embodiments, a refrigerant may be supplied to the heat diffusion channel 45 and/or the additional heat diffusion channel 55, and thermal energy transmitted through the substrate transfer channel 35 may be reduced by the refrigerant.

In addition, although an embodiment in which the metal plate 25 and the second insulating plate 30 are in contact with each other is shown in FIG. 16, the present invention is not limited thereto, and the metal plate 25 and the second insulating plate 30 may be spaced apart from each other. In this case, in addition to the heat diffusion channel 45 formed by the first insulating plate 20 and the metal plate 25 (and the additional heat diffusion channel 55 formed by the chamber 10 and the first insulating plate 20 shown in FIGS. 17 and 18), an another additional heat diffusion channel (not shown) may be formed by the metal plate 25 and the second insulating plate 30. In some embodiments, a refrigerant may be supplied to the heat diffusion channel 45, the additional heat diffusion channel 55, and/or the another additional heat diffusion channel (not shown), and thermal energy transmitted through the substrate transfer channel 35 can be removed by the refrigerant.

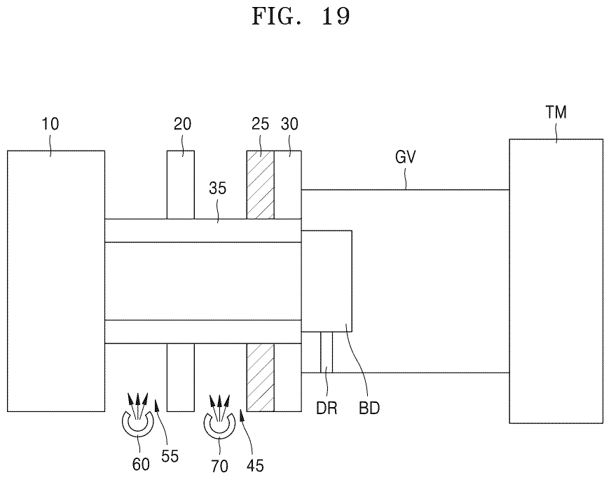

FIG. 19 schematically shows a substrate processing device according to embodiments of the inventive concept. The substrate processing device according to the embodiments may be a variation of the substrate processing device according to the above-described embodiments. In addition, the substrate processing device according to the embodiments may introduce configurations of a heat shielding device according to the above-described embodiments. Hereinafter, repeated descriptions of the embodiments will not be given herein.

Referring to FIG. 19, in some embodiments, the substrate processing device may further include a refrigerant supplier 70 supplying refrigerant to a space between the first insulating plate 20 and the metal plate 25 (i.e. the heat diffusion channel 45). Additionally, in some cases, the substrate processing device may further include an additional refrigerant supplier 60 for supplying refrigerant to an additional space between the outer wall of the chamber 10 and the first insulating plate 20 (i.e. the additional heat diffusion channel 55).

Alternatively, the refrigerant supplier 70 and/or the additional refrigerant supplier 60 may control at least one of a temperature and a flow rate of refrigerants such that the temperature of the space 45 is lower than the temperature of the additional space 55. For example, as shown in FIG. 19, the refrigerant supplier 70 disposed between the first insulating plate 20 and the metal plate 25 may reduce the temperature of the refrigerant supplied by the refrigerant supplier or may increase the flow rate of the refrigerant supplied by the refrigerant supplier. Accordingly, the temperature of the space 45 between the first insulating plate 20 and the metal plate 25 may be maintained lower than the temperature of the additional space 55 between the outer wall of the chamber 10 and the first insulating plate 20. In an embodiment, the refrigerant may be at least one of liquid, gas and air and the mixture thereof.

A method of controlling the refrigerant supplier 70 and/or the additional refrigerant supplier 60 so that the temperature of the space 45 is lower than the temperature of the additional space 55 may be implemented in various ways. For example, without an additional refrigerant supplier 60, only a refrigerant supplier 70 may be installed in the space 45 between the first insulating plate 20 and the metal plate 25, and the outer circumferential surface of the substrate transfer channel 35 may be cooled by the refrigerant supplied by the refrigerant supplier 70. By doing so, the heat diffusion channel 45 can be maintained at a lower temperature than the additional heat diffusion channel 55. As an another example, similar to the embodiment shown in FIG. 7, a refrigerant supplier 70 may be installed in the outer heat diffusion channel 45 (i.e. the space between the first insulating plate 20 and the metal plate 25) and at least one gap (not shown) may be formed in the first insulating plate 20, and a suction part may be formed in the inner heat diffusion channel 55 (i.e. the space between the outer wall of the chamber 10 and the first insulating plate 20). In this case, a first outer circumferential surface of the substrate transfer channel 35 exposed by the heat diffusion channel 45 may be cooled in advance compared with a second outer circumferential surface thereof exposed by the additional heat diffusion channel 55.

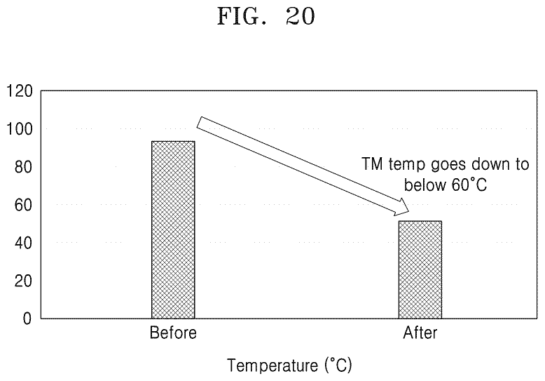

FIG. 20 shows a comparison between the surface temperature of the transfer chamber due to thermal energy generated during the high-temperature process of the chamber in a substrate processing device according to embodiments of the inventive concept and a conventional substrate processing device respectively. The high temperature process may be performed in a chamber comprising, for example, a susceptor (heating block) heated to 550 degrees Celsius, a showerhead heated to 220 degrees Celsius, and a reactor wall heated to 150 degrees Celsius.

Components and external surfaces accessible to users in the substrate processing device must be kept within a predetermined temperature range for safety. This temperature range differs from the material of the surface. For example, the temperatures of the components or external surfaces of the equipment that can be touched by users should be less than 95 degrees Celsius for metal, less than 80 degrees Celsius for glass material, and less than 65 degrees Celsius for insulators such as plastic or rubber.

Conventionally, insulators have been introduced to the outer wall of the substrate processing device to satisfy such safety requirements, but the disclosure according to the embodiments additionally introduces a substrate processing device to reduce a heat transmission from the reaction chamber of the high-temperature process to other chambers (particularly, the low-temperature process chamber) through the gate valve (GV) and the transfer chamber (TM) to minimize that a heat in the high-temperature process chamber affects the process carried out in the low-temperature process chamber.

The substrate processing apparatus according to embodiments of the inventive concept has the purpose of minimizing the temperature effect on adjacent apparatuses, and in particular, a first insulating plate 20 having an insulating effect and a metal plate 25 having a heat resistance property are installed around the substrate transfer channel 35 so that proper temperature management may be achieved. As shown in FIG. 20, the substrate processing device according to the prior art, even though it meets safety requirements, makes the temperature of the surrounding transfer chamber (that is, the transfer chamber connected to the reaction chamber through the gate valve) 90 degrees Celsius or higher. This may lead to a problem of adversely affecting the process in adjacent chambers (particularly in case of a reaction chamber where the low temperature process is performed). On the other hand, according to the embodiments of the inventive concept, the temperature of the adjacent transfer chamber can be maintained at less than 60 degrees Celsius, so the temperature effect on the surrounding equipment such as the transfer chamber can be minimized.

The above disclosure provides a number of embodiments and a number of exemplary advantages of a substrate processing device including the heat shielding device. For the sake of brevity, only a limited number of combinations of related features have been described. It should be understood, however, that features of any example may be combined with features of any other example. Moreover, it should be understood that these advantages are non-limiting and that no particular advantage is specified or required in any particular example embodiment.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing device comprising:
a chamber;
a first insulating plate disposed on an outer wall of the chamber;
a second insulating plate spaced apart from the first insulating plate;
a metal plate disposed between the first insulating plate and the second insulating plate; and
a substrate transfer channel formed to pass through the first insulating plate, the second insulating plate, and the metal plate,
wherein the metal plate comprises a heat reflection layer formed thereon facing the first insulating plate.

2. The substrate processing device of claim 1, wherein
the first insulating plate includes glass fiber and a thermosetting resin, and the thermal conductivity of the first insulating plate is less than 0.3 W/mK.

3. The substrate processing device of claim 1, wherein
the metal plate comprises stainless steel containing at least 12 wt % of chromium.

4. The substrate processing device of claim 3,
wherein the metal plate comprises 18Cr-8Ni based stainless steel.

5. The substrate processing device of claim 1,
wherein the metal plate has a thermal conductivity of less than 30 W/mK.

6. The substrate processing device of claim 5,
wherein the heat reflection layer comprises a chromium layer, and
wherein the chromium layer is in direct contact with the metal plate.

7. The substrate processing device of claim 1,
wherein the second insulating plate comprises polycarbonate.

8. The substrate processing device of claim 1, further comprising:
a gate valve connected to the substrate transfer channel.

9. The substrate processing device of claim 8,
wherein at least a part of the gate valves comprises an additional metal plate having a thermal conductivity of less than 30 W/mK.

10. The substrate processing device of claim 1, wherein
the substrate transfer channel extends along a first direction,
at least a portion of a thermal energy emitted from the chamber is reflected by the metal plate to be transmitted along a second direction different from the first direction.

11. The substrate processing device of claim 10, wherein
one surface of the metal plate is polished to perform a heat reflecting function against the thermal energy.

12. The substrate processing device of claim 1,
wherein the metal plate extends along the second direction and is configured not to include a bending portion.

13. A substrate processing device comprising:
a chamber;
a first insulating plate disposed on an outer wall of the chamber; and
a metal plate forming a heat diffusion channel together with the first insulating plate,
wherein a substrate transfer channel for transfer of the substrate in a first direction is formed between the first insulating plate and the metal plate,
wherein the metal plate extends along a second direction different from the first direction, and
wherein the heat diffusion channel is formed along the second direction, and the metal plate is configured to have no bending portion around the substrate transfer channel in the heat diffusion channel.

14. The substrate processing device of claim 13, wherein
thermal energy emitted from the chamber is reflected by the metal plate to be transmitted along the heat diffusion channel extending in the second direction.

15. The substrate processing device of claim 13, wherein
the metal plate has a thermal conductivity of less than 30 W/mK.

16. The substrate processing device of claim 13, further comprising:
a gate valve connected to the chamber,
wherein the gate valve includes a body unit and a driving unit for moving the body unit.

17. The substrate processing device of claim 16, wherein
at least a portion of the body unit includes an additional metal plate having a thermal conductivity of less than 30 W/mK.

18. A substrate processing device comprising:
a chamber;
a first insulating plate disposed on an outer wall of the chamber, the first insulating plate including glass fiber and a thermosetting resin; and
a metal plate spaced apart from the first insulating plate by a predetermined distance, the metal plate including 18Cr-8Ni based stainless steel,
wherein a chromium layer is formed in direct contact with a surface of the 18Cr-8Ni based stainless steel of the metal plate facing the first insulating plate, and
wherein a space exists between the first insulating plate and the metal plate.

19. The substrate processing device of claim 18, further comprising:
a second insulating plate disposed outside the metal plate.

20. The substrate processing device of claim 18, further comprising:
a refrigerant supplier supplying refrigerant to the space.

21. The substrate processing device of claim 20, wherein
an additional space is formed between the outer wall and the first insulating plate, the substrate processing device further includes an additional refrigerant supplier supplying refrigerant to the additional space, and
the refrigerant supplier and the additional refrigerant supplier control at least one of a temperature and a flow rate of the refrigerant so that a temperature of the space is lower than a temperature of the additional space.
